(19) United States
(12) Patent Application Publication
(10) Pub. No.: US 2025/0285893 A1
(43) Pub. Date: Sep. 11, 2025

(54) WAFER SAMPLE SEGMENTATION APPARATUS

(71) Applicant: Samsung Electronics Co., Ltd., Suwon-si (KR)

(72) Inventors: Sangseok Hong, Suwon-si (KR); Daeyong Kim, Suwon-si (KR); Jooyoung Park, Suwon-si (KR); Jungjun Park, Suwon-si (KR); Hoseok Song, Suwon-si (KR); Okkee Sim, Suwon-si (KR); Myoungho Jung, Suwon-si (KR)

(21) Appl. No.: 19/039,082

(22) Filed: Jan. 28, 2025

(30) Foreign Application Priority Data
Mar. 11, 2024 (KR) 10-2024-0034062

(51) Int. Cl. H01L 21/67; H01L 21/68

(52) U.S. Cl. CPC H01L 21/67282; H01L 21/67092; H01L 21/681

(57) ABSTRACT

A wafer sample segmentation apparatus is disclosed and the wafer sample segmentation apparatus according to some embodiments comprises a supporting part supporting one region of a sample of a wafer while facing one surface of the sample; a pressing part facing the other surface facing one surface of the sample and capable of pressing a pair of pressing regions positioned on both sides of one region in the sample by being moved toward the sample; an indentation part facing the other surface of the sample and capable of moving toward the sample to indent a segmentation region positioned between the pair of pressing regions in the sample; and a measuring part capable of measuring a pressing force acting on the sample along the pressing direction of the pressing part.

### CROSS-REFERENCE TO RELATED APPLICATIONS

This application claims priority to and the benefit under 35 U.S.C. § 119(a)-(d) of Korean Patent Application No. 10-2024-0034062 filed on Mar. 11, 2024, in the Korean Intellectual Property Office, the entire contents of which are incorporated herein by reference.

### FIELD

The present disclosure relates to a wafer sample segmentation apparatus for manufacturing a specimen by segmenting a wafer sample.

### BACKGROUND

A semiconductor manufacturing process may include various processes, and in order to determine whether results of the various processes are normal, a cross-section of a specimen manufactured from a wafer that has gone through the process may be inspected.

The cross-section of the specimen may be inspected in any of a variety of ways, such as by taking high-magnification images. For measuring the uniformity of the microstructure of the specimen, it may be advantageous for the cross-section of the fabricated specimen to have high shape density.

### SUMMARY

The embodiments seek to provide a wafer sample segmentation apparatus that may improve the segmentation density and the cross-section flatness.

The embodiments seek to provide a wafer sample segmentation apparatus that may effectively control and keep constant a pressing force acting on the sample.

The embodiments seek to provide a wafer sample segmentation apparatus that may uniformly provide the pressing force to the sample.

The embodiments seek to provide a wafer sample segmentation apparatus that may adjust a position relationship between components for the segmentation.

The embodiments seek to provide a wafer sample segmentation apparatus that may align the crystal direction of the sample and the blade direction of the indentation part.

A wafer sample segmentation apparatus according to an embodiment includes a supporting part, a pressing part, an indentation part, and a measuring part.

The supporting part faces the sample one surface of the wafer and supports one region of the sample. The pressing part faces the other surface facing one surface of the sample and is moved toward the sample to press a pair of pressing regions positioned on both sides of the one region in the sample.

The indentation part faces the other surface of the sample and moves toward the sample to indent a segmentation region positioned between the pair of pressing regions in the sample. The measuring part measures a pressing force acting on the sample along the pressing direction of the pressing part.

On the other hand, in a wafer sample segmentation apparatus according to an embodiment, the supporting part may support one region of a sample while facing one surface of the sample of a wafer, and the pressing part may face the other surface opposite to one surface of the sample and move toward the sample to press the pressing region of the sample.

The indentation part may face the other surface of the sample and move toward the sample to indent the segmentation region of the sample; and the measuring part may measure a pressing force acting on the sample along the pressing direction of the pressing part,

If the measurement value of the measuring part falls within a pressing reference range, the indentation part may be moved toward the sample to indent the segmentation region.

On the other hand, in a wafer sample segmentation apparatus according to an embodiment, the supporting part may support one region of a sample while facing one surface of the sample of a wafer. The pressing part may be provided as a pair to each face the other surface of one surface of the sample, and move toward the sample to press a pair of pressing regions positioned on both sides of the one region in the sample.

The indentation part may face the other surface of the sample and move toward the sample to indent a segmentation region positioned between the pair of pressing regions in the sample, wherein the supporting part may be positioned between the pair of pressing parts with reference to the arrangement direction of the pair of pressing parts, and the pair of pressing parts may be movable along the arrangement direction.

Embodiments may provide the wafer sample segmentation apparatus that may improve a segmentation accuracy and a flatness of a cross-section.

Embodiments may provide the wafer sample segmentation apparatus that may effectively control and keep constant a pressing force acting on the sample.

Embodiments may provide the wafer sample segmentation apparatus that may uniformly provide the pressing force to the sample.

Embodiments may provide the wafer sample segmentation apparatus that may adjust position relationships between components for the segmentation.

Embodiments may provide the wafer sample segmentation apparatus that may align the crystal direction of the sample and the blade direction of the indentation part.

According to some aspects, a wafer sample segmentation apparatus is generally described. In some embodiments, the apparatus comprises a supporting part supporting one region of a sample of a wafer while facing one surface of the sample; a pressing part facing the other surface facing one surface of the sample and capable of pressing a pair of pressing regions positioned on both sides of the one region of the sample by being moved toward the sample; an indentation part facing the other surface of the sample and capable of moving toward the sample to indent a segmentation region positioned between the pair of pressing regions in the sample; and a measuring part capable of measuring a pressing force acting on the sample along the pressing direction of the pressing part.

In some embodiments, the apparatus comprises: a supporting part supporting one region of a sample of a wafer while facing one surface of the sample; a pressing part facing the other surface opposite to the one surface of the sample and capable of moving toward the sample to press the pressing region of the sample; an indentation part facing the other surface of the sample and capable of moving toward the sample to indent the segmentation region of the sample; and a measuring part capable of measuring a measurement value acting on the sample along the pressing direction of the pressing part, wherein: if the measurement value of the measuring part falls within a pressing reference range, the indentation part is capable of moving toward the sample to indent the segmentation region.

In some embodiments, the apparatus comprises: a supporting part supporting one region of a sample of a wafer while facing one surface of the sample; a pressing part provided as a pair facing the other surface opposite to the one surface of the sample of the sample, and capable of moving toward the sample to press a pair of pressing regions positioned on both sides of the one region in the sample; and an indentation part facing the other surface of the sample and capable of moving toward the sample to indent a segmentation region positioned between the pair of pressing regions in the sample, wherein the supporting part is positioned between the pair of pressing parts with reference to an arrangement direction of the pair of pressing parts, and the pair of pressing parts is movable along the arrangement direction.

### BRIEF DESCRIPTION OF THE DRAWINGS

FIG. 1 is a view showing a wafer sample segmentation apparatus according to some embodiments.

FIG. 2 is a view showing a sample moving part of a wafer sample segmentation apparatus according to some embodiments.

FIG. 3 is a view showing a sample segmentation part of a wafer sample segmentation apparatus according to some embodiments.

FIG. 4 is a view showing a sample being placed in a sample arrangement part, according to some embodiments.

FIG. 5 is a view showing a supporting part, a pressing part, and an indentation part, according to some embodiments.

FIG. 6 is a view showing an arrangement state in which a sample is placed in a sample arrangement part during a sample segmentation process, according to some embodiments.

FIG. 7 is a view showing a supporting state in which a sample is supported by a supporting part during a segmentation process of a sample, according to some embodiments.

FIG. 8 is a view showing a pressing state in which a sample is pressed by a pressing part during a sample segmentation process, according to some embodiments.

FIG. 9 is a view showing an indentation state in which a sample is indented by an indentation part during a sample segmentation process, according to some embodiments.

FIG. 10 is a view showing a segmentation state in which a sample is segmented and a specimen is produced during a sample segmentation process, according to some embodiments.

FIG. 11 is a view showing a support part provided in a sample segmentation part, according to some embodiments.

FIG. 12 is a view showing a pressing part provided in a sample segmentation part, according to some embodiments.

FIG. 13 is a view showing an indentation part provided in a sample segmentation part, according to some embodiments.

FIG. 14 is a view showing a sample arrangement part provided in a sample segmentation part, according to some embodiments.

FIG. 15 is a view showing a camera provided in a sample segmentation part, according to some embodiments.

FIG. 16 is a view showing an alignment process of a pressing part and an indentation part, according to some embodiments.

FIG. 17 is a view showing an alignment process between a crystal direction of a sample and a blade direction of an indentation part, according to some embodiments.

FIG. 18 is a block diagram showing a control relationship between components through a controller, according to some embodiments.

### DETAILED DESCRIPTION

In the following detailed description, only certain embodiments of the present disclosure have been shown and described, simply by way of illustration.

As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

In the present specification, duplicate descriptions for the same components are omitted.

Also, in present specification, it is to be understood that when one component is referred to as being “connected” or “coupled” to another component, it may be connected or coupled directly to the other component or be connected or coupled to another component with the other component intervening therebetween. On the other hand, in this specification, it is to be understood that when one component is referred to as being “connected or coupled directly” to another component, it may be connected or coupled to the other component without another component intervening therebetween.

It is also to be understood that the terminology used herein is only for the purpose of describing particular embodiments, and is not intended to be limiting of the disclosure.

Singular forms are to include plural forms unless the context clearly indicates otherwise.

It will be further understood that term “comprises” or “have” used in the present specification specify the presence of stated features, numerals, steps, operations, components, parts, or a combination thereof, but does not preclude the presence or addition of one or more other features, numerals, steps, operations, components, parts, or a combination thereof.

Also, as used herein, the term “and/or” includes any plurality of combinations of items or any of a plurality of listed items. In this specification, “A or B” may include “A”, “B”, or “A and B”.

The specimen of the wafer may be produced through a segmentation method. The segmentation method may be useful for producing the specimen with the cross-section created along the crystal direction of the wafer, and the specimen with the cross-section may be produced by segmenting the wafer or the sample prepared by subdividing from the wafer.

Generally, the smoother the cross-section of the specimen produced using the segmentation method, the better the inspection accuracy. To smoothly create the cross-section of the specimen, a method of splitting the sample by indenting the sample provided with a bending force may be used.

In the segmentation method, the smoothness of the cross-section depends on the magnitude and uniformity of the bending force acting on the sample, and may vary depending on the angle between the blade direction defined in the indentation tool and the crystal direction of the sample.

Therefore, by producing the specimen via segmenting the wafer sample, stably controlling the bending force acting on the specimen, providing a uniform bending force to the sample using the cross-section as a reference, and effectively aligning the crystal direction of the sample and the blade direction of the indentation tool are relatively important tasks in this field of technology.

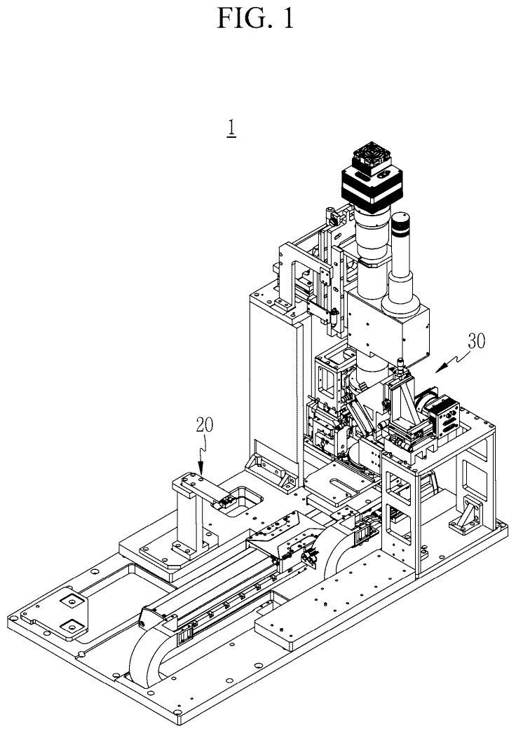

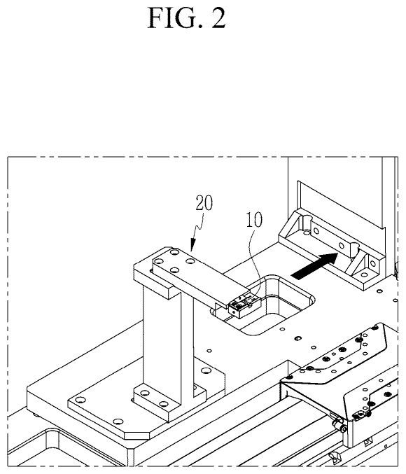

FIG. 1 shows a wafer sample segmentation apparatus 1 according to some embodiments. The wafer sample segmentation apparatus 1 includes a sample moving part 20 that moves a sample 10 (See FIG. 2) of the wafer and a sample segmentation part 30 that segments the sample 10 received through the sample moving part 20.

Various processes may be performed in a semiconductor manufacturing process used in the semiconductor industry. To determine the results of the various processes, a cross-section inspection of a semiconductor substrate, for example a wafer, may be performed.

In some embodiments, the sample 10 of the wafer may be a piece subdivided from the wafer, and if possible, the wafer itself may be used as the sample 10. Hereinafter, for better understanding and ease of explanation, the sample 10 of the wafer is described as a piece divided (e.g., subdivided) from the wafer.

The sample moving part 20 may move the sample 10 toward the sample segmentation part 30 while the sample 10 is placed. The sample moving part 20 may be moved toward the sample segmentation part 30 as is, or a part of the sample moving part 20 may be moved toward the sample segmentation part 30. If necessary, at least part of the sample segmentation part 30 may be moved toward the sample moving part 20 to receive the sample 10.

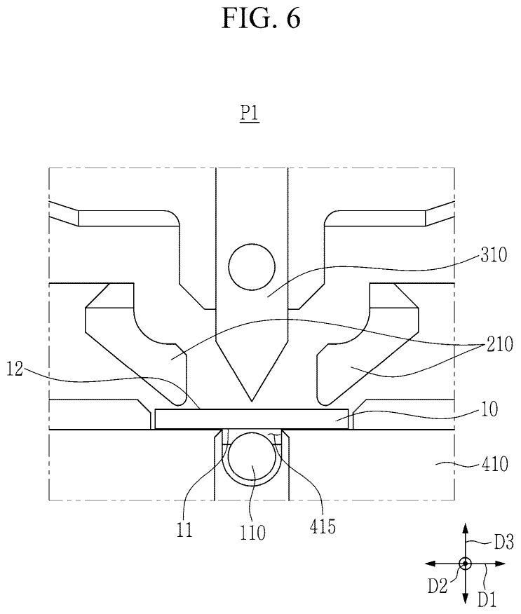

The sample segmentation part 30 is prepared to segment the sample 10 transported from the sample moving part 20. The sample segmentation part 30 may produce a specimen with a cross-section cut by segmenting the sample 10. The cross-section may be extended in a direction across one surface 11 (see FIG. 6) of the sample 10 and may be created through the segmentation of the sample 10.

The cross-section of the specimen may be inspected by taking pictures using high resolution or high magnification photography. For measuring the uniformity of the microstructure of the specimen, it may be advantageous for the cross-section of the manufactured specimen to have high formation accuracy.

In other words, the smoother the cross-section of the specimen, the more advantageous it may be for high-precision inspection. Therefore, a specimen having a cross-section with high planarity and high accuracy may be more advantageous for the specimen inspection. Some embodiments seek to effectively produce the specimen including the cross-sections of the specimen with high formation accuracy.

FIG. 2 shows the sample moving part 20 of the wafer sample segmentation apparatus 1. The sample moving part 20 may be provided together with a base part where the sample segmentation part 30 described above is placed, or the sample moving part 20 may be provided to have a separate base and be movable.

The sample moving part 20 may accommodate and move the sample 10 described above. The sample 10 may be divided from the wafer in advance before being accommodated in the sample moving part 20 and provided to the sample moving part 20. However, if necessary, it is possible for the sample 10 to be subdivided while being accommodated in the sample moving part 20.

FIG. 2 shows one sample moving part 20, but the number of the sample moving parts 20 may vary depending on the need. Additionally, the way that the sample moving part 20 transports the sample 10 to the sample segmentation part 30 may also vary.

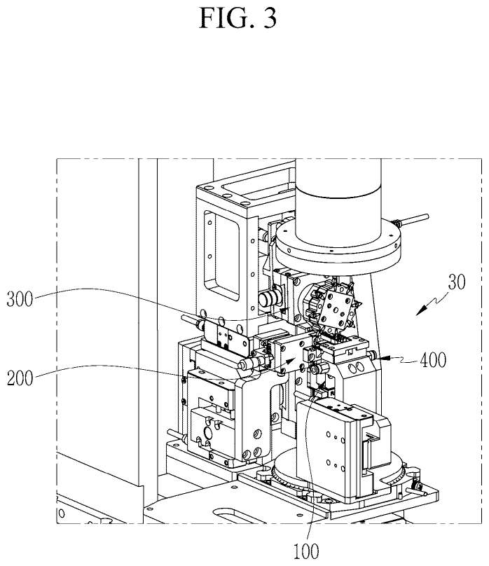

FIG. 3 shows the sample segmentation part 30 of the wafer sample segmentation apparatus 1. The sample segmentation part 30 may produce the cross-section of the specimen by receiving the sample 10 through the sample moving part 20 and segmenting it.

The sample segmentation part 30 may include at least one among a sample arrangement part 400, in which a sample 10 is arranged, a supporting part 100 supporting the sample 10 arranged in the sample arrangement part 400, a pressing part 200 that generates a bending force on the sample 10 by pressing the sample 10 supported by the supporting part 100, and an indentation part 300 that indents the sample 10 so that the sample 10 in which the bending force occurs is split.

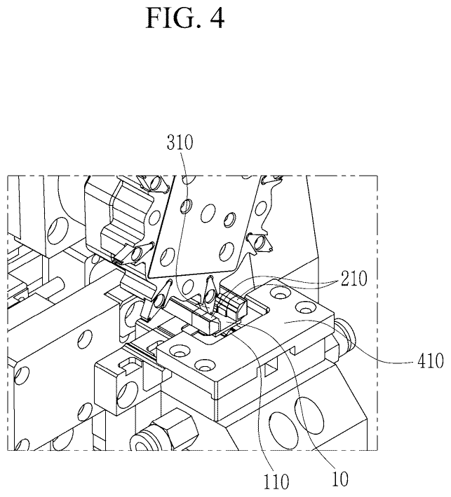

FIG. 4 shows the shape in which the sample 10 is arranged in the sample arrangement portion 410 of the sample arrangement part 400. In some embodiments, the sample arrangement part 400 includes a sample arrangement portion 410 in which the sample 10 is arranged. The sample 10 may be segmented while being arranged in the sample arrangement portion 410 to create a specimen.

The pressing part 200 may include a pressing portion 210 for pressing the sample 10, and the indentation part 300 may include an indentation portion 310 for indenting the sample 10. The sample arrangement portion 410 may be positioned toward one surface 11 of the sample 10, and the pressing portion 210 and the indentation portion 310 may be positioned toward the other surface 12 (see FIG. 6) of the sample 10.

The sample 10 may be positioned on the sample arrangement portion 410 and segmented by the pressing portion 210 and the indentation portion 310 to produce the specimen.

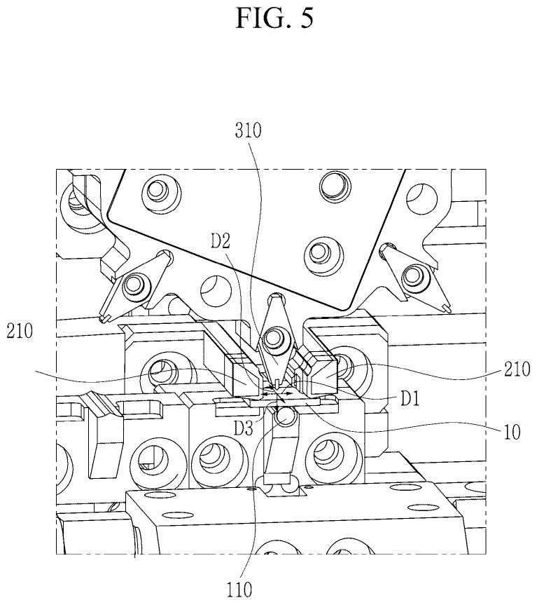

FIG. 5 shows the supporting portion 110, the pressing portion 210, and the indentation portion 310 with the above-mentioned sample arrangement portion 410 omitted in the drawing.

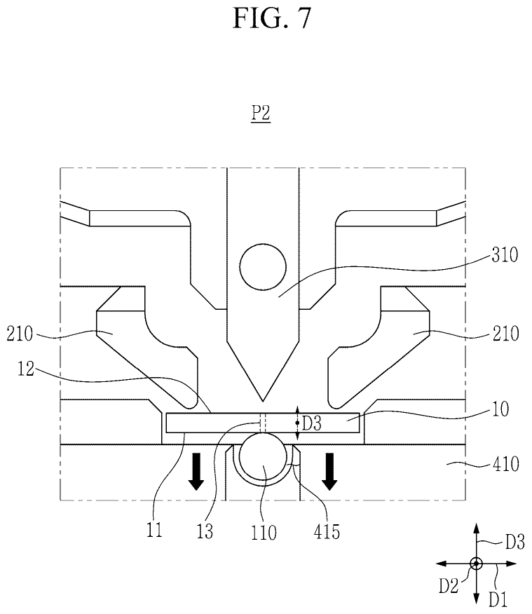

The supporting portion 110 faces one surface 11 of the sample 10 of the wafer and supports one region 13 (see FIG. 7) of the sample 10. The one region 13 may be defined as the part supported by the supporting portion 110 in the sample 10. The one region 13, that is the support region, may be defined in any of a variety of parts of the sample 10.

The supporting portion 110 may support the sample 10 by being in contact with the sample 10 in a form of a point, a line, or a surface. FIG. 5 shows that the supporting portion 110, extended in the form of a bar or an arm, supports one surface 11 of the sample 10 in the form of a line or surface.

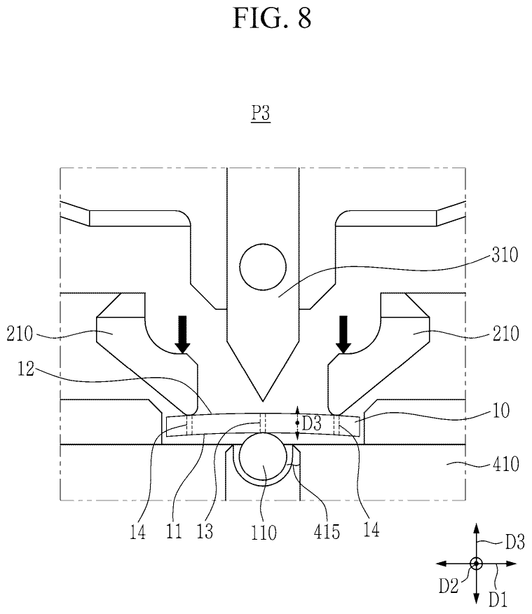

The pressing portion 210 faces the other surface 12 opposite to one surface 11 of the sample 10, and moves toward the sample 10 to press the pressing region 14 (see FIG. 8) of the sample 10. The pressing region 14 may refer to a portion pressed by the pressing portion 210 in the sample 10.

The position of the pressing region 14 relative to one region 13 of the aforementioned supporting portion 110 may vary. In some embodiments, the pressing region 14 may be spaced apart from the one region 13, and may be defined as a pair and positioned on both sides of the one region 13 in the sample 10. In some embodiments, the pressing portion 210 may be provided as a pair and arranged to be spaced apart on both sides of the supporting portion 110.

The pressing portion 210 may move toward the other surface 12 of the sample 10, such that each pressing portion 210 spaced apart on the other surface 12 of the sample 10 presses each of the pressing regions 14 of the sample 10.

The pressing portion 210 may press the sample 10 by being in contact with the sample 10 in the form of a point, a line, or a surface. FIG. 5 shows the pressing portion 210, extended in the form of a bar or an arm, pressing one surface 11 of the sample 10 in the form of a line or surface.

The other surface 12 of the sample 10 may be the opposite surface of one surface 11 of the sample 10. That is, the pressing portion 210 may be positioned on the opposite side of the supporting portion 110 with the sample 10 as a reference and may press the sample 10 toward the supporting portion 110.

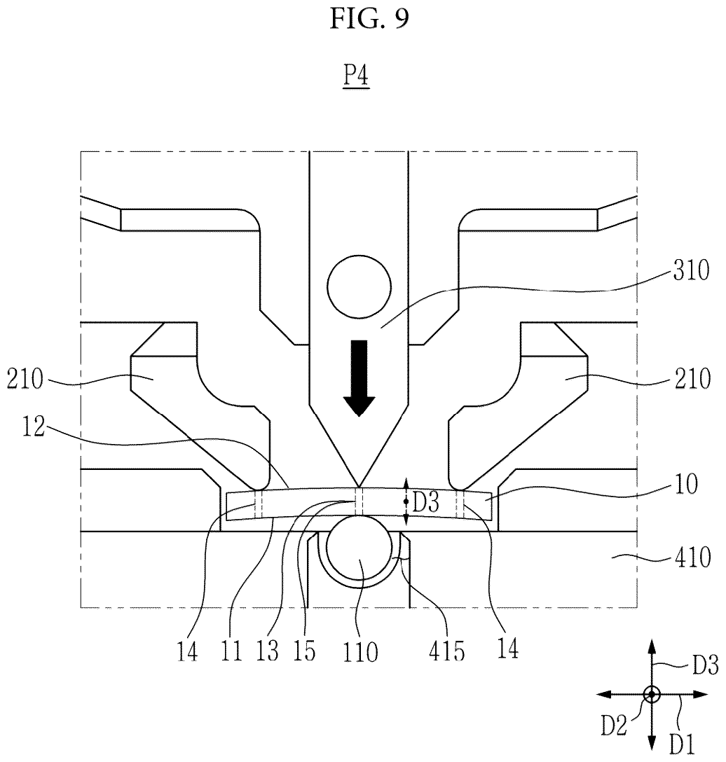

The indentation portion 310 may face the other surface 12 of the sample 10 and be moved toward the sample 10 to indent the segmentation region 15 (see FIG. 9) positioned between the pair of pressing regions 14 in the sample 10.

The segmentation region 15 may be a region where the indentation occurs by being in contact with the indentation portion 310 in the sample 10

The segmentation region 15 may be defined between the aforementioned pair of pressing regions 14.

That is, the indentation portion 310 may indent the other surface 12 of the sample 10 by being positioned between the pair of pressing units 210 and moved toward the sample 10. When the indentation occurs in the sample 10, which is pressed by the pressing portion 210, a bending force is generated. Splitting may occur with the indentation mark as a starting point due to the concentration of the stress, and accordingly, a specimen having a cross-section crossing one surface 11 and the other surface 12 of the sample 10 may be produced.

In some embodiments, a first direction D1, a second direction D2, and a third direction D3 may be defined for better understanding and ease of description. The first direction D1 may be parallel to one surface 11 of the sample 10, may be the length direction of the sample 10, and may be a direction in which the pair of pressing portion 210 and the indentation portion 310 are aligned/arranged.

The second direction D2 may be parallel to one surface 11 of the sample 10, and may be defined to cross the first direction D1. For example, the second direction D2 may be the width direction of the sample 10 and an elongated direction of the supporting portion 110, the pressing portion 210, and the indentation portion 310. The second direction D2 may be defined as substantially orthogonal to the first direction D1.

The third direction D3 may be a direction passing through one surface 11 of sample 10, and may be defined as a direction crossing the first direction D1 and the second direction D2. The third direction D3 may be the thickness direction of the sample 10 and the movement direction of the pressing portion 210 and the indentation portion 310.

FIG. 6 to FIG. 10 show the process in which the sample 10 is segmented in the wafer sample segmentation apparatus 1 and a specimen is produced.

FIG. 6 shows the arrangement state P1 of the sample 10 during the segmentation process of the sample 10. In the arrangement state P1, the sample 10 may be arranged in the sample arrangement portion 410, and the sample 10 may be supported by the sample arrangement portion 410.

The sample arrangement portion 410 may be in a state that is contact with the sample 10, and the pressing portion 210 and the indentation portion 310 may be in a state where the pressing portion 210 and the indentation portion 310 are spaced apart from sample 10. The pressing portion 210 and the indentation portion 310 may be in a state where the pressing portion 210 and the indentation portion 310 are moved away along the third direction D3 from the other surface 12 of the sample 10.

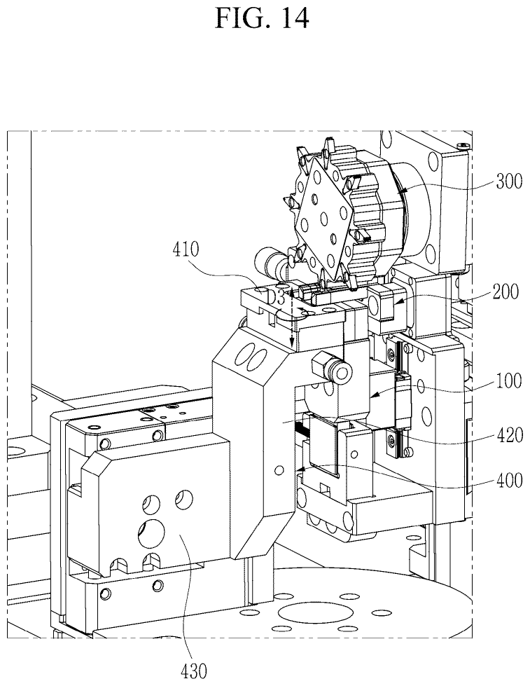

In the arrangement state P1, the alignment of the crystal direction D4 (see FIG. 14) of the sample 10, the alignment of the pressing portion 210, and the alignment of the indentation portion 310 may be performed. The detailed description of these alignment process will be provided later.

FIG. 7 shows a supporting state P2 of the sample 10 during the segmentation process of the sample 10. In the supporting state P2, as the sample arrangement portion 410 moves in the third direction D3 away from one surface 11 of the sample 10, one surface 11 of the sample 10 may be supported by the supporting portion 110.

In some embodiments, the sample arrangement portion 410 may include an accommodation space 415 capable of accommodating the supporting portion 110. In the aforementioned arrangement state P1, the supporting portion 110 may be accommodated in the accommodation space 415 of the sample arrangement portion 410 and may be spaced apart from one surface 11 of the sample 10.

From the arrangement state P1, the sample arrangement portion 410 may be moved along the third direction D3 to be separated from one surface 11 of sample 10 to become the supporting state P2. By moving the sample arrangement portion 410, the supporting portion 110 may be reflexively drawn out from the accommodation space 415, and support one surface 11 of the sample 10, and support one region 13 of the sample 10.

In some embodiments, the position of the supporting portion 110 may be fixed and may serve as a reference for determining the position of other components. However, if necessary, the supporting portion 110 may be moved in the third direction D3 and drawn out directly from the accommodation space 415 of the sample arrangement portion 410.

FIG. 8 shows the pressing state P3 of the sample 10 during the segmentation process of the sample 10. In the pressing state P3, the pressing portion 210 moves toward the other surface 12 of the sample 10, so that sample 10 may be pressed toward one surface 11 of the sample 10 (e.g., along third direction D3).

The pressing portion 210 may be provided as a pair and press the pair of pressing regions 14. The pair of pressing units 210 may be moved together. When the other surface 12 of the sample 10 is pressed by the pair of pressing portion 210, the bending force centered on the supporting portion 110 may act on the sample 10. In some embodiments, the pressing force by the pressing portion 210 may act as a bending force for the sample 10.

The supporting portion 110 may be positioned at the center between the pair of pressing units 210 with reference to the arrangement direction of the pair of the pressing units 210 (e.g., first direction D1). In other words, one region 13 of the sample 10 by the supporting portion 110 may be positioned in the center between the pair of pressing regions 14.

Accordingly, the pressing force or the bending force acting on the sample 10 centered on the one region 13 by the supporting portion 110 uniformly acts on the sample 10, thereby improving the formation accuracy of the cross-section.

FIG. 9 shows the indentation state P4 of the sample 10 during the segmentation process of the sample 10. In the indentation state P4, the indentation portion 310 may engrave the indentation on the other surface 12 of the sample 10 while moving in the third direction D3 toward the other surface 12 of the sample 10.

If the indentation occurs in the sample 10 where the bending force is generated by the pressing portion 210, the splitting may occur while the stress is concentrated around the indentation. In some embodiments, the method of splitting the sample 10 by using the bending force involves a relatively shallow depth of the indentation by the indentation portion 310 and may increase the formation accuracy of the cross-section compared to segmenting the entire sample 10 by using the indentation portion 310. In other words, the cross-section may, in some embodiments, be as smooth as a mirror.

The segmentation region 15 of the sample 10 indented by the indentation portion 310 may be positioned between the pair of pressing regions 14 and may coincide with one region 13 of the supporting portion 110 described above. That is, the one region 13 and the segmentation region 15 may overlap along the third direction.

Through this, the uniformity of the pressing force/bending force acting on the sample 10 centered on the indentation mark may be improved, thereby forming the cross-section of the specimen more smoothly, according to some embodiments.

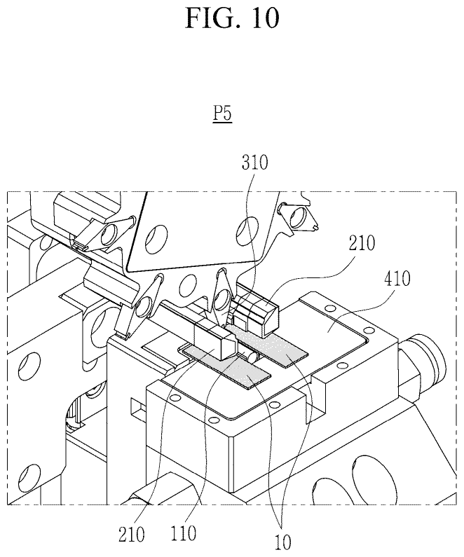

FIG. 10 shows the segmentation state P5 of the sample 10 during the segmentation process of the sample 10. The sample 10 split in the above-described indentation state P4 may be segmented into two specimens and arranged on the sample arrangement portion 410.

The sample arrangement portion 410 may move the specimens to an apparatus for the inspection, or the user may directly collect the specimens from the sample arrangement portion 410. The specimen produced from the sample 10 may be used to evaluate the results of the process through a photography method of the cross-section.

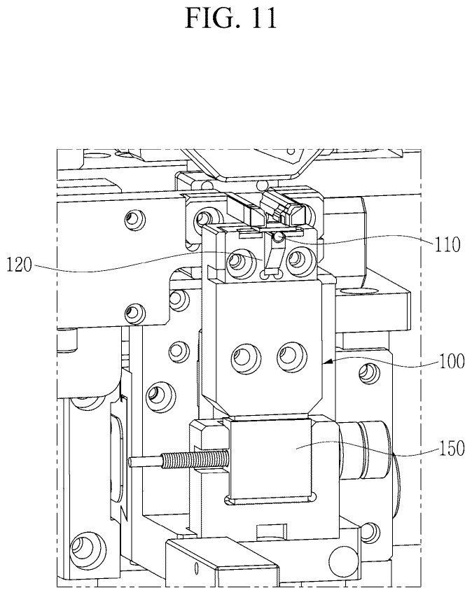

FIG. 11 shows the supporting part 100 of the wafer sample segmentation apparatus 1.

The supporting part 100 may include the supporting portion 110 described above and a supporting body 120. The supporting body 120 may be arranged such that the supporting body 120 is spaced apart from the sample 10. The supporting body 120 may be spaced apart from the sample 10 along the second direction D2.

The supporting portion 110 may be in the form of a bar/arm extending from the supporting body 120 toward the sample 10. The supporting portion 110 may extend from the supporting body 120 and be positioned to face one surface 11 of the sample 10.

The supporting portion 110 may include a contact portion that is in directly contact with one region 13 of the sample 10 and a reinforcing portion to reinforce the rigidity of the contact portion. The reinforcing portion may be positioned on the opposite side of the sample 10 with the contact portion as a reference, and may reinforce the rigidity of the contact portion to which the pressing force by the pressing portion 210 is transmitted.

The position and shape of the supporting body 120 may vary, and FIG. 11 shows, according to some embodiments, a block-shaped supporting body 120 positioned lower than the sample 10.

A measuring part 150 may be provided in the supporting part 100. The measuring part 150 may be configured to measure the pressing force acting on the sample 10 along the pressing direction of the pressing portion 210.

The pressing force provided to the sample 10 is transmitted to the supporting portion 110 and the supporting body 120 by the pressing portion 210. The measuring part 150 may be provided on the supporting body 120 and measure the pressing force transmitted to the supporting body 120 through the supporting portion 110.

The measuring part 150 may be positioned such that the measuring part 150 is spaced apart from sample 10 along the pressing direction (e.g., the third direction D3) by the pressing portion 210 of the pressing body 220. For example, the measuring part 150 may be provided at the end of the supporting body 120, with the pressing direction as a reference, to support the supporting body 120 and to receive and/or facilitate the measurement of the pressing force acting on the sample 10.

FIG. 11 shows the supporting body 120 arranged lower than the sample 10, and the measuring part 150 that is coupled to the lower end of the supporting body 120 to support the supporting body 120, according to some embodiments.

However, the position of the measuring part 150 is not necessarily limited as above, and the measuring part 150 may be built into the supporting body 120 or may be provided on the upper side of the supporting body 120. The measuring part 150 may be provided as a load cell type coupled to the supporting body 120.

When manufacturing the specimen with the cross-section, the pressing force acting on the sample 10 is a relatively important factor in improving the smoothness of the cross-section.

Specifically, the smoothness of the specimen cross-section is a relatively important factor and may at least partially rely on a generation speed of the cross-section that is constant and appropriate, according to some embodiments.

If the bending force of the sample 10 is too large, a damage may occur in the cross-section during the splitting process of the sample 10, and if the bending force is too small, the depth of the indentation mark caused by the indentation portion 310 may become deeper and the damage of the cross-section may occur due to the contact with the indentation portion 310.

In addition, if the bending force of the sample 10 fluctuates unstably, it may be difficult to obtain the uniform cross-section flatness, which may be detrimental to the cross-section inspection.

As the wafer sample segmentation apparatus 1 according to some embodiments is provided with the measuring part 150 in the supporting part 100 to support the sample 10, during the segmentation process of the sample 10, the pressing force, or the bending force acting on the sample 10, may be adjusted to the constant and appropriate level to produce the specimen.

For example, in some embodiments, if a measurement value of the measuring part 150 in the pressing state P3 in which the pressing portion 210 presses the sample 10 is within a pressing reference range, the indentation portion 310 may be moved toward the sample 10 to indent the segmentation region 15.

The pressing reference range is a range of the pressing force that is theoretically and/or experimentally determined in advance to improve the formation accuracy of the cross-section of the specimen. By performing the indentation process when the pressing force acting on the sample 10 through the pressing portion 210 is within the pressing reference range, the specimen of the cross-section with high formation accuracy may be produced.

The control of the pressing force acting on the sample 10 may be relatively important, not only in the pressing state P3, but also in the indentation state P4. For example, during the indentation process of the sample 10, the pressing force acting on the sample 10 may be increased by the indentation portion 310 in addition to the pressing portion 210.

As mentioned above, since the generation speed of the cross-section is a relatively important factor in improving the formation accuracy of the cross-section, and it may be advantageous that the speed at which this cross-section occurs is maintained during the indentation process, some embodiments may keep the pressing force acting on the sample 10 appropriate and constant through the measurement value measured by the measuring part 150 even during the indentation process.

For example, in the indentation process in which the pressing portion 210 presses the sample 10 and the indentation portion 310 presses and indents the sample 10, the indentation portion 310 may be moved to indent the segmentation region 15 so that the measurement value of the measuring part 150 falls within the indentation reference range.

The indentation reference range may be a range of the pressing force during the indentation process that is theoretically and/or experimentally determined in advance to improve the formation accuracy of the cross-section of the specimen. In some embodiments, the indentation reference range may be the same as the aforementioned pressing reference range, or at least a portion of the range may be defined within the pressing reference range, or at least a portion of the pressing reference range may be defined within the indentation reference range.

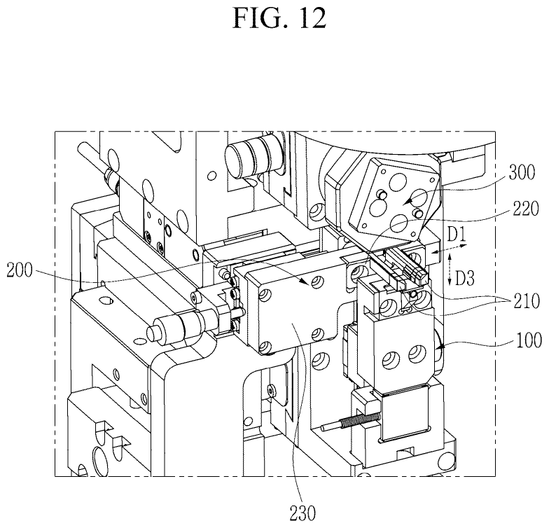

FIG. 12 shows the pressing part 200 of the wafer sample segmentation apparatus 1, according to some embodiments. The pressing part 200 may include a pressing body 220 in addition to the pressing portion 210 described above.

The pressing body 220 may be arranged to be spaced apart from the sample 10, and the pair of pressing portions 210 may be protruded from the pressing body 220 to face the other surface 12 of the sample 10.

The pair of pressing portions 210 may be arranged along the first direction D1, and the pressing bodies 220 may be spaced apart in the second direction D2 with respect to the sample 10. The pressing portion 210 may extend along the second direction D2 from the pressing body 220 toward the sample 10 and be positioned to face the other surface 12 of the sample 10.

The pressing body 220 may be provided in the form of a block from which the pressing portion 210 is protruded, and the pair of pressing portions 210 may be protruded together from one pressing body 220.

Meanwhile, the pressing body 220 may be arranged to be movable along the pressing direction and the arrangement direction. That is, the pressing body 220 may be provided to be movable along the first direction D1 and the third direction D3, and the pressing portion 210 may be moved by the movement of the pressing body 220 to press the sample 10 or the position thereof may be adjusted.

The pressing part 200 may include a pressing moving part 230 for moving the pressing body 220. The pressing moving part 230 may be provided in various types and shapes that may move the pressing body 220.

FIG. 12 shows, as an example, the pressing moving part 230 in the form of a block to which the pressing body 220 is movably coupled. The pressing body 220 may be capable of moving in the first direction D1 and the third direction D3 while coupled to the pressing moving part 230, and the pressing moving part 230 may include an actuator for the pressing portion 210 that generates the moving force of the pressing body 220.

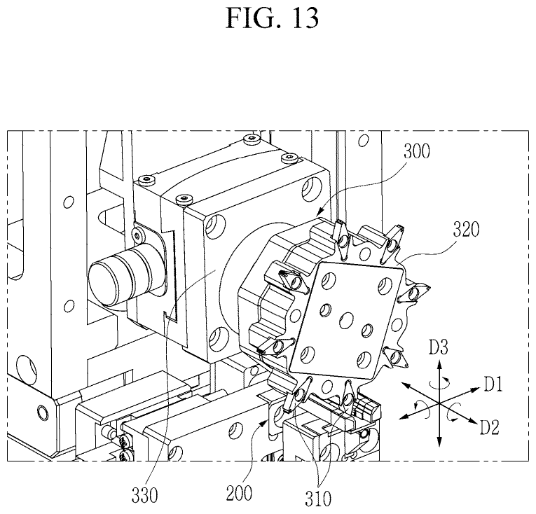

FIG. 13 shows the indentation part 300 of the wafer sample segmentation apparatus 1, according to some embodiments. The indentation part 300 may include an indentation body 320 along with the indentation portion 310 described above.

The indentation body 320 may be arranged to be spaced apart from sample 10, and the indentation portion 310 may be provided on the indentation body 320 to indent the sample 10 by being protruded from the indentation body 320 toward the other surface 12 of the sample 10.

The position of the indentation body 320 for the sample 10 may vary. For example, as shown in FIG. 13, the indentation body 320 may be arranged to be spaced apart in the third direction D3 approximately for the sample 10, and the indentation portion 310 may be provided in a protruded form from the indentation body 320 toward the other surface 12 of the sample 10.

The indentation body 320 may be provided with a plurality of indentation portions 310. The indentation portion 310 is in direct contact with the sample 10 and indents the sample 10, and, as a durability of each indentation portion 310 progresses through the repeated indentation processes, the indentation portion 310 that has undergone a predetermined number of the indentation processes may be replaced with a new indentation portion 310.

For this purpose, the indentation body 320 may be pre-equipped with a plurality of indentation portions 310, and the indentation body 320 may perform the indentation process by replacing the indentation portion 310 currently in use with another indentation portion 310 after a predetermined number of indentation processes have been performed.

There may be various ways in which the indentation body 320 is provided with a plurality of indentation portions 310 to enable replacement. For example, as shown in FIG. 13, the indentation body 320 may have an approximately circular cross-section shape and be rotatable about a rotation axis parallel to the second direction D2, and the plurality of indentation portions 310 may be arranged along the circumferential direction of the indentation body 320.

When the use number of the indentation portion 310 facing the current sample 10 exceeds a predetermined number, the indentation body 320 may be rotated to arrange another indentation portion 310 adjacent to the indentation portion 310 currently in use to face the sample 10.

The indentation part 300 may be prepared so that the indentation portion 310 may move in a direction parallel to one surface 11 of the sample 10. The indentation portion 310 may be moved in at least one direction among the first direction D1, the second direction D2, and the third direction D3.

The indentation body 320 may be provided to move the indentation portion 310, and the movement of the indentation portion 310 may be accomplished by the movement of the indentation body 320.

The indentation part 300 may include an indentation moving part 330 for moving the position of the indentation body 320. The indentation body 320 may be movably coupled to the indentation moving part 330. The indentation moving part 330 may include an indentation actuator to generate the moving force of the indentation body 320.

Furthermore, the indentation portion 310 may be arranged to be rotatable around the rotation axes parallel to each of the first direction D1 parallel to one surface 11 of the sample 10, the second direction D2 parallel to one surface 11 of the sample 10 and orthogonal to the first direction D1, and the third direction penetrating the sample 10.

Since the indentation portion 310 may be rotatably provided on the indentation body 320 and/or the indentation body 320 may be rotated by the indentation moving part 330, rotational movement of the indentation portion 310 may occur.

The indentation portion 310 may be rotated around the rotation axis parallel to the first direction D1 so that the blade of the indentation portion 310 may be aligned to be parallel to the other surface 12 of the sample 10. Specifically, the end of the indentation portion 310 facing the sample 10 may be defined as a blade which may make contact with the sample 10 and indent the sample 10.

The blade may extend along the second direction D2 to be in contact with the sample 10. However, if the blade is not parallel to the other surface 12 of the sample 10, some of the segmentation region 15 of the sample 10 may be indented first along the second direction D2, and the rest may be indented later, which may deteriorate the formation accuracy for the entire cross-section of the specimen.

Therefore, the indentation portion 310 may be rotated around the rotation axis parallel to the first direction D1 and aligned in parallel with the other surface 12 of the specimen such that the segmentation region 15 may be simultaneously indented as a whole.

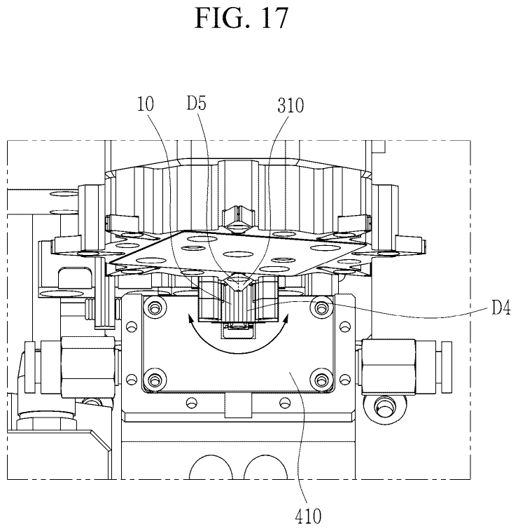

The indentation portion 310 may be rotated around the rotation axis parallel to the second direction D2, so that the indentation direction of the sample 10 of the blade may be precisely matched to the third direction D3. Additionally, as the indentation portion 310 is rotated around the rotation axis parallel to the third direction D3, the blade direction D5 (see FIG. 17), where the blade extends, and the crystal direction D4 (see FIG. 17) present in the sample 10 may be aligned to be matched.

FIG. 14 shows the sample arrangement part 400 of the wafer sample segmentation apparatus 1, according to some embodiments. The sample arrangement part 400 may include the sample arrangement portion 410 described above and a sample arrangement body 420.

The sample arrangement portion 410 may provide a work space where the sample 10 is arranged and the segmentation process is performed, and the sample arrangement portion 410 may be provided on the sample arrangement body 420 arranged such that the sample arrangement portion 410 is spaced apart from the sample 10 and supported by the sample arrangement body 420.

The sample arrangement body 420 is arranged to be spaced apart from sample 10, and the shape and position thereof may vary. For example, the sample arrangement body 420 may be positioned on the opposite side of the above-described pressing part 200 and indentation part 300 centered on the sample 10, for appropriate utilization of space.

The sample arrangement portion 410 may be moved along the pressing direction and may be provided to rotate the sample 10 about the rotation axis parallel to the pressing direction.

In some embodiments, the sample arrangement portion 410 may be moved along the third direction D3 or rotated about the rotation axis parallel to the third direction D3 with respect to the sample arrangement body 420. In some embodiments, the sample arrangement body 420 may be directly moved and rotated.

For example, the sample arrangement part 400 may include a sample arrangement moving part 430. The sample arrangement moving part 430 may be coupled to and may move the sample arrangement body 420. The sample arrangement moving part 430 may include an actuator for the sample 10 arrangement to provide the moving force for the sample arrangement body 420.

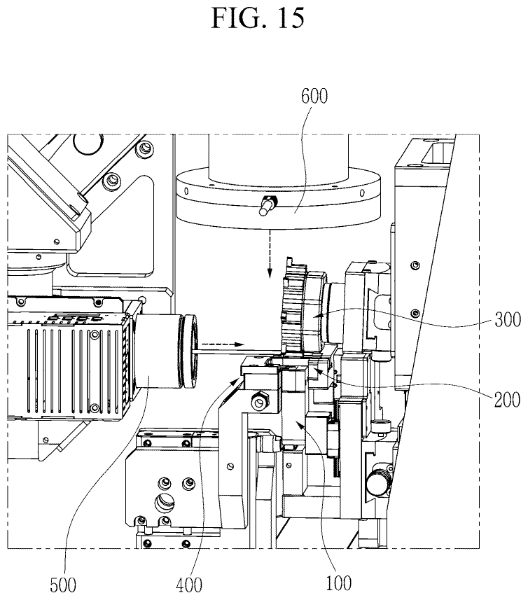

FIG. 15 shows a camera provided in the wafer sample segmentation apparatus 1, according to some embodiments.

The process of segmenting the sample 10 to produce the specimen having the cross-section involves relatively precise control, and for this purpose, at least one or more cameras may be installed to identify and align the position relationships between components.

In an embodiment, the wafer sample segmentation apparatus 1 may include a first camera 500, and the first camera 500 may be spaced apart from the sample 10 along the protrusion direction of the pressing portion 210 to image the pressing portion 210 and the supporting portion 110.

The first camera 500 may be positioned to be spaced apart from the sample 10 in the second direction D2, and may be positioned on the opposite side of the supporting portion 110 and the pressing portion 210 with respect to the sample 10. The first camera 500 may photograph at least one of the supporting portion 110, the pressing portion 210, and the indentation portion 310.

The wafer sample segmentation apparatus may include a second camera 600, and the second camera 600 may be spaced apart from the sample 10 along the pressing direction and photograph the crystal direction D4 of the sample 10.

The second camera 600 may be arranged away from sample 10 along the third direction D3, and may be positioned on the opposite side of the sample arrangement portion 410 and the supporting portion 110 with the sample 10 as the center. The second camera 600 may be positioned above the sample 10. The second camera 600 may photograph at least one of the other surface 12 of the sample 10 and the indentation portion 310.

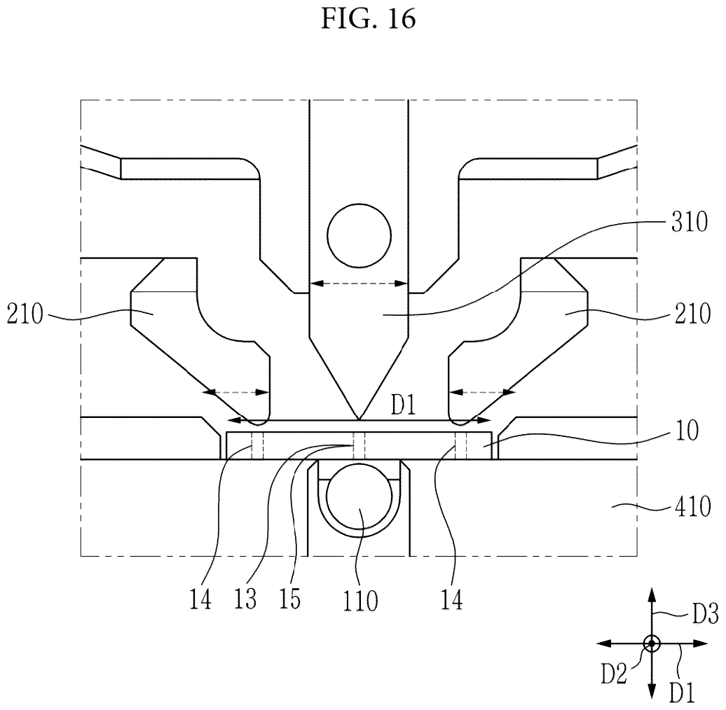

FIG. 16 shows the pressing portion 210 and the indentation portion 310 moving along the first direction D1 in the wafer sample segmentation apparatus 1, according to some embodiments.

In some embodiments, the pair of pressing portion 210 may be arranged to be movable along the arrangement direction of the pair of pressing portion 210, for example the first direction D1, as described above.

As mentioned above, in order to provide the uniform pressing force to the sample 10, it may be advantageous that the supporting region of the sample 10 by the supporting portion 110 is positioned in the center between the pair of pressing regions 14 defined by the pair of pressing portions 210.

Accordingly, in some embodiments, the pair of pressing portions 210 may be moved along the arrangement direction such that the supporting portion 110 may be positioned at the center between the pair of pressing portions 210, and the position relationship between the pressing portion 210 and the supporting portion 110 may be confirmed directly by the user or through the photographic information of the first camera 500 described above.

Also, as mentioned above, in order to improve the formation accuracy of the cross-section of the sample 10, it may be advantageous for the segmentation region 15 and the support region to coincide. In some embodiments, the segmentation region 15 and the support region may overlap each other in the third direction, and accordingly, the indentation portion 310 and the supporting portion 110 may be aligned along the pressing direction so that the segmentation region 15 and one region 13 by the supporting portion 110 may be matched.

For example, the indentation portion 310 may be aligned with the supporting portion 110 along the third direction D3 by adjusting the position thereof along the first direction D1 with the position of the supporting portion 110 as a reference. The position of the indentation portion 310 may be checked directly by the user or through the shooting information of the first camera 500.

FIG. 17 shows a process of aligning the crystal direction D4 of the sample 10 and the blade direction D5 of the indentation portion 310, according to some embodiments.

The sample 10 provided from the wafer has the crystal direction D4 like the wafer, and if the crystal direction D4 and the blade direction D5 of the indentation portion 310 are aligned in parallel, it may be advantageous to improve the smoothness of the cross-section.

As described above, in the wafer sample segmentation apparatus 1 according to some embodiments, at least one of the indentation portion 310 and the sample arrangement portion 410 may be rotated around the rotation axis parallel to the third direction D3.

The indentation portion 310 may adjust the blade direction D5 through the rotation, and the sample arrangement portion 410 may adjust the crystal direction D4 of the sample 10 through the rotation. The alignment process of the blade direction D5 and the crystal direction D4 may be checked directly by the user with the naked eye or based on shooting information from the second camera 600.

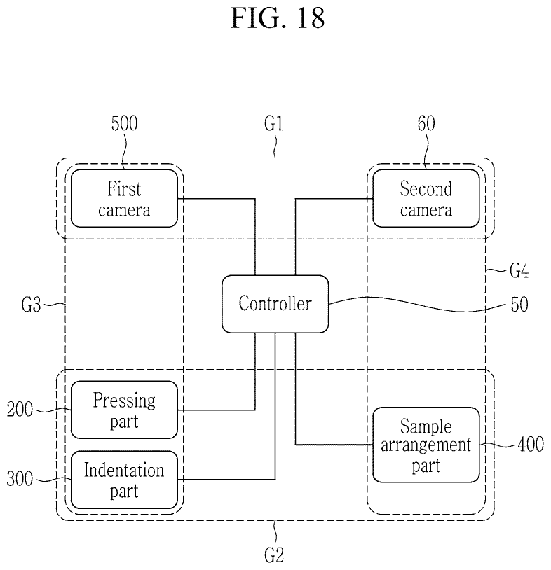

FIG. 18 shows a block diagram showing a control relationship by a controller 50 of the wafer sample segmentation apparatus 1 in some embodiments.

In some embodiments, a controller 50 may control the movement of at least one of the pressing portion 210 and the indentation portion 310. The controller 50 may receive the measurement value from the measuring part 150.

Information input group G1 for the controller 50 may comprise the above-described first camera 500 and second camera 600. The components of the information input group G1 may contribute to control activities of the controller 50 by providing information to the controller 50.

Controlled group G2 for the controller 50 may comprise the above-described pressing part 200, indentation part 300, and sample arrangement part 400. The movements of the components of the controlled group G2 may be controlled according to the instructions of the controller 50. The pressing part 200 may be defined as including the aforementioned measuring part 150.

For the first camera 500, the pressing part 200, and the indentation part 300, the control of the pressing part 200 and the indentation part 300 may be performed based on the shooting information of the first camera 500 as the first group G3 for the controller 50.

For the second camera 600 and the sample arrangement part 400, the control of the sample arrangement part 400 may be performed based on the shooting information of the second camera 600 as the second group G4 for the controller 50. As described above, when the indentation portion 310 rotates around the third direction D3, the indentation portion 310 may also be defined as being included in the second group G4.

The controller 50 may align the position relationship between the supporting portion 110, the pressing portion 210, and the indentation portion 310 according to the first direction D1 based on the shooting information of the first camera 500. The controller 50 may adjust the mutual position relationship by moving the pressing portion 210 and the indentation portion 310 along the first direction D1 around the supporting portion 110. If necessary, a position reference other than supporting portion 110 may be selected.

The controller 50 may align the crystal direction D4 of the sample 10 and the blade direction D5 of the indentation portion 310 based on the captured information of the second camera 600. The controller 50 may rotate the sample arrangement portion 410 or rotate the indentation portion 310 to adjust the rotation position relationship between them.

As described above, the controller 50 may control the movement of at least one of the pressing portion 210 and the indentation portion 310 based on the measurement value of the measuring part 150.

The controller 50 may receive the measurement value of the measuring part 150 and may determine whether the measurement value belongs within the pressing reference range or the indentation reference range, thereby controlling at least one of the movement of the pressing portion 210 or the movement of the indentation portion 310.

While the present disclosure has been particularly shown and described with reference to specific embodiments thereof, it will be understood by those skilled in the art that various changes in form and detail may be made therein without departing from the spirit and scope of the disclosure as defined by the following claims.

What is claimed is:

1. A wafer sample segmentation apparatus, comprising:
a supporting part supporting one region of a sample of a wafer while facing one surface of the sample;
a pressing part facing the other surface facing one surface of the sample and capable of pressing a pair of pressing regions positioned on both sides of the one region of the sample by being moved toward the sample;
an indentation part facing the other surface of the sample and capable of moving toward the sample to indent a segmentation region positioned between the pair of pressing regions in the sample; and
a measuring part capable of measuring a pressing force acting on the sample along the pressing direction of the pressing part.

2. The wafer sample segmentation apparatus of claim 1, wherein:
in a pressing state where the pressing part is pressing the sample, if the measurement value of the measuring part falls within the pressing reference range, the indentation part is moved toward the sample to indent the segmentation region.

3. The wafer sample segmentation apparatus of claim 1, further comprising:
a supporting body arranged away from the sample,
the supporting part is protruded from the supporting body to face one surface of the sample, and
the measuring part is provided on the supporting body and is capable of measuring the pressing force transmitted to the supporting body through the supporting part.

4. The wafer sample segmentation apparatus of claim 3, wherein:
the measuring part is provided at the end of the supporting body, with reference to the pressing direction, to support the supporting body.

5. The wafer sample segmentation apparatus of claim 3, wherein:
the measuring part is provided as a load cell type coupled to the supporting body.

6. The wafer sample segmentation apparatus of claim 1, wherein:
the pressing part is provided as a pair and is capable of pressing the pair of pressing regions, and
the supporting part is positioned in the center, with reference to the arrangement direction of the pair of pressing parts, between the pair of pressing parts.

7. The wafer sample segmentation apparatus of claim 6, further comprising:
a pressing body arranged away from the sample, wherein:
the pair of pressing parts protruding from the pressing body to face the other surface of the sample, and
the pressing body is movable along the pressing direction and the arrangement direction.

8. The wafer sample segmentation apparatus of claim 7, wherein:
a first camera spaced apart from the sample along a protrusion direction of the pressing part and capable of photographing the pressing part and the supporting part.

9. The wafer sample segmentation apparatus of claim 1, wherein:
the indentation part and the supporting part are aligned along the pressing direction so that the segmentation region and the one region of the sample overlap each other along the pressing direction.

10. The wafer sample segmentation apparatus of claim 9, further comprising:
an indentation body arranged away from the sample, wherein
the indentation part is protruded from the indentation body toward the other surface of the sample, and
the indentation body is provided so that the indentation part is movable in a direction parallel to one surface of the sample.

11. The wafer sample segmentation apparatus of claim 1, wherein:
the indentation part is provided to be rotatable about a rotation axis respectively parallel to a first direction parallel to the one surface of the sample, a second direction parallel to the one surface of the sample and vertical to the first direction, and a third direction penetrating the sample.

12. The wafer sample segmentation apparatus of claim 1, further comprising:
a sample arrangement part where the sample and the supporting part are positioned, wherein
the sample arrangement part is arranged to rotate the sample about a rotation axis parallel to the pressing direction.

13. The wafer sample segmentation apparatus of claim 12, further comprising:
a second camera spaced away from the sample along the pressing direction and capable of photographing the crystal direction of the sample.

14. The wafer sample segmentation apparatus of claim 1, further comprising:
a controller that receives the measurement value from the measuring part and is capable of controlling the movement of at least one of the pressing part or the indentation part.

15. A wafer sample segmentation apparatus comprising:
a supporting part supporting one region of a sample of a wafer while facing one surface of the sample;
a pressing part facing the other surface opposite to the one surface of the sample and capable of moving toward the sample to press the pressing region of the sample;
an indentation part facing the other surface of the sample and capable of moving toward the sample to indent the segmentation region of the sample; and
a measuring part capable of measuring a measurement value acting on the sample along the pressing direction of the pressing part, wherein:
if the measurement value of the measuring part falls within a pressing reference range, the indentation part is capable of moving toward the sample to indent the segmentation region.

16. The wafer sample segmentation apparatus of claim 15, wherein:
in an indentation process, where the pressing part is capable of pressing the sample and the indentation part is capable of pressing and indenting the sample, the indentation part is capable of moving to indent the segmentation region so that the measurement value of the measuring part falls within an indentation reference range.

17. The wafer sample segmentation apparatus of claim 16, wherein:
a controller receiving the measurement value of the measuring part and determining whether the measurement value falls within the pressing reference range or the indentation reference range such that at least one of the movement of the pressing part or the movement of the indentation part is controlled.

18. A wafer sample segmentation apparatus comprising:
a supporting part supporting one region of a sample of a wafer while facing one surface of the sample;
a pressing part provided as a pair facing the other surface opposite to the one surface of the sample, and capable of moving toward the sample to press a pair of pressing regions positioned on both sides of the one region in the sample; and
an indentation part facing the other surface of the sample and capable of moving toward the sample to indent a segmentation region positioned between the pair of pressing regions in the sample,
wherein the supporting part is positioned between the pair of pressing parts with reference to an arrangement direction of the pair of pressing parts, and
the pair of pressing parts is movable along the arrangement direction.

19. The wafer sample segmentation apparatus of claim 18, wherein:
the pair of pressing parts are capable of moving along the arrangement direction so that the supporting part is positioned centrally between the pair of pressing parts.

20. The wafer sample segmentation apparatus of claim 18, further comprising:
a pressing body arranged spaced apart from the sample, wherein:
the pair of pressing parts is protruded from the pressing body to face the other surface of the sample, and
the pressing body is movable along the pressing direction and the arrangement direction.
